(19) United States
(12) Patent Application Publication
(10) Pub. No.: US 2025/0311241 A1
(43) Pub. Date: Oct. 2, 2025

(54) INTEGRATION METHOD OF VERTICAL DRAM WITH PERIPHERAL CIRCUIT

(71) Applicant: Tokyo Electron Limited, Tokyo (JP)

(72) Inventors: Soo Doo CHAE, Albany, NY (US); Sunghil LEE, Albany, NY (US); Hojin KIM, Albany, NY (US); Arkalgud SITARAM, Albany, NY (US)

(73) Assignee: Tokyo Electron Limited, Tokyo (JP)

(21) Appl. No.: 18/622,764

(22) Filed: Mar. 29, 2024

(51) Int. Cl. H10B 80/00; H01L 23/00; H01L 25/00; H01L 25/065; H01L 25/18; H10B 12/00

(52) U.S. Cl. CPC H10B 80/00; H01L 24/08; H01L 24/80; H01L 25/0657; H01L 25/18; H01L 25/50; H10B 12/033; H10B 12/05; H10B 12/315; H01L 2224/08145; H01L 2224/80006; H01L 2224/80895; H01L 2224/80896; H01L 2924/1431; H01L 2924/1436

(57) ABSTRACT

A method of integrating a semiconductor device with periphery circuit including connecting the semiconductor device to a periphery circuit that includes forming a vertical DRAM cell on a substrate, flipping the vertical DRAM cell, grinding and removing the substrate to expose a first epitaxial layer, forming a first wafer embedded with a first bonding pad on a hard mask that is deposited on a plurality of bit lines, flipping the vertical DRAM cell back, forming a second wafer embedded with a second bonding pad that is formed on an insulating layer, connecting the insulating layer to the periphery circuit through a second contact that is embedded in the insulating layer, bonding the first wafer and the second wafer by hybrid bonding, and forming back end of lines on top of the DRAM cell.

### FIELD OF THE INVENTION

This disclosure relates to semiconductor fabrication and, in particular, to a method of forming a semiconductor device and a method of integrating the semiconductor device with a peripheral circuit.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

The density of vertical stacked DRAM has been remarkably increased due to the reduced size of memory cells. Currently, 4F² vertical DRAM has been obtained by using vertical channel transistors for the memory cells. However, such cells and the peripheral logic circuitry are typically formed on the same semiconductor substrate which requires a larger area on the semiconductor substrate. The continuous demand for higher capacity and performance in computer memory places constant pressure on the DRAM industry to achieve advances in density, speed, power efficiency and other areas.

### SUMMARY

The present disclosure provides a method of fabricating a vertical DRAM device by forming a gate transistor with Si/SiGe epitaxial growth and processing hybrid bonding through wafer backside.

Aspects of the disclosure provides a method of manufacturing a semiconductor device. The method includes forming a stack of alternatively deposited semiconductor layers on a surface of a substrate, the stack of alternative deposited layers including a first buffer layer formed on the substrate, a first epitaxial layer formed on the first buffer layer, a second buffer layer formed on the first epitaxial layer, and a second epitaxial layer formed on the second epitaxial layer, etching the second epitaxial layer to form a plurality of vertical channel structures, depositing a gate dielectric layer and a gate metal layer on at least one of the plurality of channel structures to form a plurality of vertical gate all around (GAA) transistors, forming a plurality of vertical capacitors in a capacitor region above the plurality of vertical GAA transistors, forming an oxide layer on top of the capacitor region, and depositing a hard mask on a first metal layer formed on the second epitaxial layer.

In an embodiment, the first buffer layer and the second buffer layer include Silicon Germanium (SiGe), and the first epitaxial layer and the second epitaxial layer include Silicon (Si).

In an embodiment, the method of manufacturing the semiconductor device includes depositing a second metal layer on top of the second buffer layer, and etching the second metal layer to form a plurality of word lines that connect to the plurality of vertical GAA transistors.

In an embodiment, the plurality of channel structures are formed in a transistor region that is filled with interlayer dielectric (ILD) films.

In an embodiment, the method of manufacturing the semiconductor device further includes forming a plurality of contact regions, wherein at least one of the contact regions forms on top of at least one of the plurality of vertical GAA transistors through a contact region.

In an embodiment, the plurality of contact regions include doped silicon (Si).

In an embodiment, the forming the plurality of vertical capacitors further includes depositing semiconductor material to fill spaces surrounding each of the plurality of vertical capacitors in a capacitor region, and forming an oxide layer on top of the capacitor region.

In an embodiment, the semiconductor material can include SiGe.

In an embodiment, forming a plurality of bit lines includes forming a wafer on the oxide layer by fusion bonding, flipping the semiconductor device so that the substrate is in a top position and a backside of the substrate is facing up in a vertical direction, removing the substrate and the first buffer layer to expose the first epitaxial layer, doping the first epitaxial layer, depositing the metal layer on the first epitaxial layer, forming a hard mask on the metal layer, forming an etch mask with patterns on the hard mask to uncover the plurality of bit lines, and etching the hard mask and the metal layer to form the plurality of bit lines.

In an embodiment, the method of manufacturing the semiconductor device further includes forming a first contact in the hard mask.

In an embodiment, the semiconductor device is a 4F² vertical dynamic random-access memory (DRAM) device.

In an embodiment, A method of integrating a semiconductor device with periphery circuit including connecting the semiconductor device to a periphery circuit that includes forming a vertical DRAM cell including a plurality of vertical transistors, a plurality of capacitors and an oxide layer, forming a silicon (Si) wafer on top of the oxide layer by fusion bonding, flipping the vertical DRAM cell so that a substrate is in a top position and a backside of the substrate is facing up in a vertical direction, grinding and removing the substrate to expose a first epitaxial layer, doping the first epitaxial layer, forming a first wafer embedded with a first bonding pad on a hard mask that is deposited on a plurality of bit lines, flipping the vertical DRAM cell back to its original position, forming a second wafer embedded with a second bonding pad that is formed on an insulating layer, connecting the insulating layer to the periphery circuit through a second contact that is embedded in the insulating layer, bonding the first wafer and the second wafer by hybrid bonding, and forming back end of lines (BEOL) on top of the DRAM cell to encapsulate the semiconductor device.

In an embodiment, the forming BEOL on top of the DRAM cell includes grinding and removing the silicon wafer to expose the oxide layer.

In an embodiment, the forming the plurality of bit lines includes depositing a metal layer on the first epitaxial layer, depositing the hard mask on the metal layer, an etch mask with patterns on the hard mask, and etching the hard mask and metal layer to form a plurality of bit lines.

In an embodiment, the vertical DRAM cell vertically connects to a plurality of word lines and the plurality of bit lines.

In an embodiment, the periphery circuit is under the vertical DRAM cell and vertically connects to the plurality of word lines and the plurality of bit lines through the first bonding pad and the second bonding pad.

In an embodiment, at least one of the plurality of transistors includes a vertical channel that is formed by epitaxial growth.

In an embodiment, the vertical channel is formed by etching a second epitaxial layer that is originally formed above the first epitaxial layer.

In an embodiment, the second epitaxial layer includes Si.

In an embodiment, the bonding pad includes at least one of copper (Cu), aluminum (Al), or tungsten (W).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 are cross-sectional view of a semiconductor device, in accordance with exemplary embodiments of the disclosure.

FIGS. 2-11 are cross-sectional views of a semiconductor device at various intermediate steps, in accordance with exemplary embodiments of the disclosure.

FIGS. 12-15 are cross-sectional views of a semiconductor device connecting to a periphery circuit at various intermediate steps, in accordance with exemplary embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

3D integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

As noted in the Background, there is constant demand on the memory industry to achieve advances in density, speed, power efficiency and other performance parameters. With respect to DRAM, 4F² scale has already been achieved by implementing vertical pillar transistors (VPTs), but peripheral logic circuits remain laterally spaced from the memory cell. Further, the present inventors have recognized that 4F² vertical DRAM faces challenges in that channel materials such as Indium-Gallium-Zink-Oxide (IGZO) used on pass gate transistor have high interface trap defects which may cause low operation current, increased leakage current, and other undesirable characteristics. Although 4F² vertical DRAM is highlighted in this disclosure because of its high density and low cost per bit, techniques herein apply to other designs such as 6F² DRAM.

To address the problems mentioned above, embodiments described herein include a method of forming a gate transistor with Si/SiGe epitaxial growth in the vertical channel and processing a hybrid bonding through the wafer backside to connect peripheral circuitry to the memory cells. Epitaxial growth allows precise control over the material thickness and carrier concentration, thus increasing the operational current flow and improving other transistor characteristics. Further, the hybrid bonding using wafer backside processing can improve the cell density, thus increasing the memory capacity.

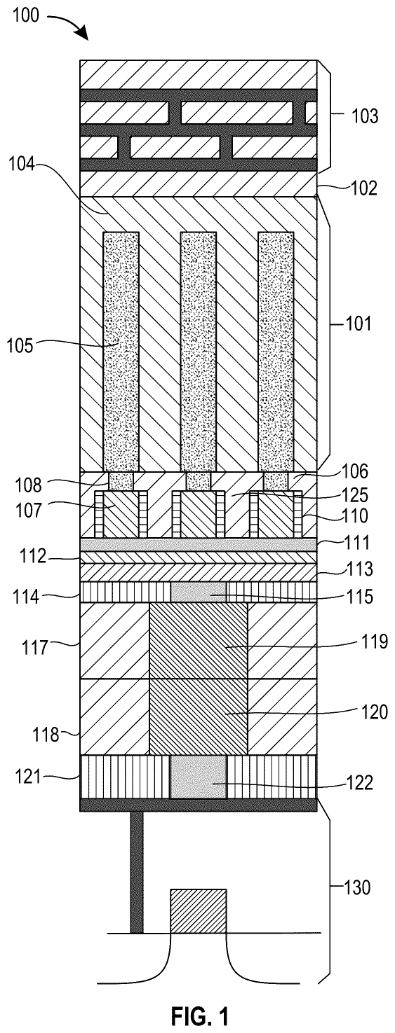

FIG. 1 shows a side view of a cross-sectional of an integrated semiconductor device (4F² vertical DRAM device) 100 in accordance with an embodiment of the present disclosure. In an embodiment, the 4F² vertical DRAM device includes a capacitor region 101, multiple doped silicon regions 108, multiple vertical channels 106, word lines (not shown), a stack of a first semiconductor layer 111, a second semiconductor layer 112, and bit lines 113. A back end of line (BEOL) stack 103 can be deposited on an oxide layer 102 formed over the capacitor region 101. The 4F² vertical DRAM device 100 can be connected to a periphery circuit 130 through a bonding pad 120. This configuration is advantageous because it saves space by vertically connecting the 4F² vertical DRAM device 100 and the periphery circuit 130.

In an embodiment, each vertical transistor 106 can be a Gate All Around (GAA) transistor that includes a channel structure 107 including an epitaxially grown semiconductor material such as Si. The channel structure 107 is surrounded and contacted by a gate structure 110 that includes a gate dielectric layer and a gate layer. The gate dielectric layer is positioned between the gate layer and the channel structure 107. The word lines (not shown) can be formed in interlayer dielectric (ILD) films 125 by connecting the gate layer 110 of each transistor in a row. Each doped silicon region 108 can be formed on top of the channel structure 107. Each doped silicon region 108 can be a contact region that contacts the capacitor 105.

In an embodiment, the capacitor region 101 can include multiple capacitors 105 that are positioned above the transistors 106. Each capacitor 105 can contact the channel structure 107 through the doped silicon region 108. Each capacitor 105 can be formed in semiconductor materials (e.g., SiGe) 104 that are below the oxide layer 102.

In an embodiment, the channel structures 107 and the ILD films 125 are positioned on top of the stack of the first semiconductor layer 111 and the second semiconductor layer 112. The second semiconductor layer 112 can be a doped silicon (Si) layer, and the second semiconductor layer can include SiGe.

In an embodiment, a first insulating layer 114 with a first contact 115 can be positioned on top of a first wafer 117. The first wafer 117 having a first embedded bonding pad 119 can be positioned on top of a second wafer 118 having a second bonding pad 120. The first bonding pad 119 and the second bonding pad 120 can be bonded together. A second insulating layer 121 with a second contact 122 can be positioned beneath the second wafer 118 and above a periphery circuit 130. Accordingly, the periphery circuit 130 can be vertically connected to the bit lines 113 and word lines (not shown) through the first contact 115, second contact 122, first embedded bonding pad 119 and second embedded bonding pad 120.

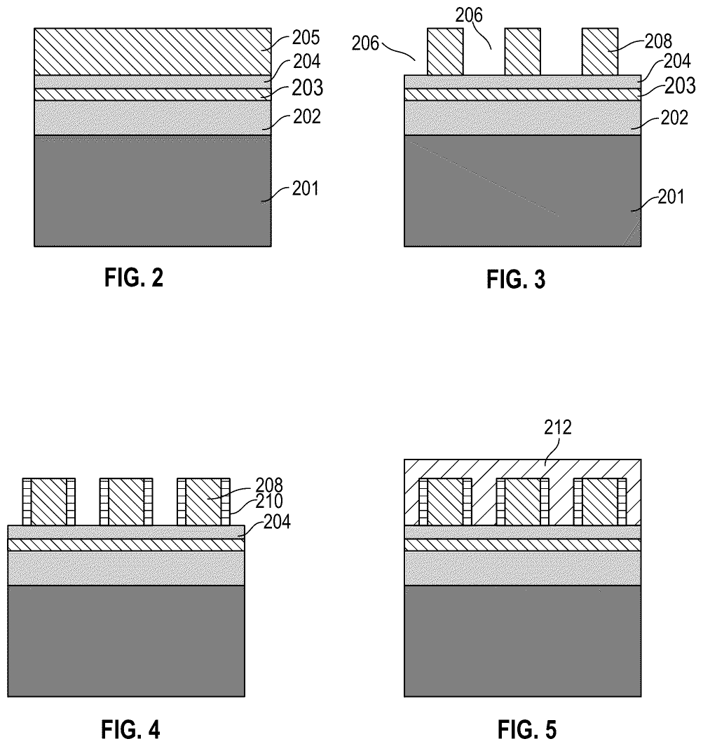

FIGS. 2-11 show cross-sectional views of various intermediary steps of an exemplary method for fabricating a 4F² vertical DRAM device 100 according to embodiments of the present disclosure.

As shown in FIG. 2, a substrate 201 of Si is provided. The substrate 201 can also be any other suitable substrate, such as Ge, SiGe, or silicon-on-insulator (SOI) substrate. A first buffer layer (e.g., SiGe) 202 can be formed on the substrate 201 and a first epitaxial layer (e.g., Si) 203 can be formed on the first buffer layer 202. A second buffer layer (e.g., SiGe) 204 can be formed on the first epitaxial layer 203 and a second epitaxial layer (e.g., Si) 205 can be formed on the second buffer layer 202. The first buffer layer 202 and the second buffer layer 204 can serve as an intermediary layer to accommodate the lattice mismatch between two materials and can also improve the quality of the resulting layer. Growing the second epitaxial layer 205 on top of the first epitaxial layer 203 can improve the purity of the second epitaxial layer 205. Accordingly, the current flow of the channel can be increased.

As shown in FIG. 3, an etch mask with patterns can be formed on the second epitaxial layer 205 and an etching process can be applied to etch the second epitaxial layer 205. The etching process can be applied to etch the second epitaxial layer 205 positioned on top of the second buffer layer 204 to produce the channel structures 208 and the spaces 206 surrounding the channel structures 208. The second buffer layer 204 can also act as an etch stop layer. The etch mask can be stripped off and removed to provide the structure shown in FIG. 3.

As shown in FIG. 4, a deposition of gate dielectric material and a metal gate layer can be performed to form a gate structure 210 of the Gate All Around (GAA) transistor. The gate dielectric material can be any suitable oxide material such as silicon dioxide (SiO₂), Hafnium oxide (HfO), Titanium oxide (TiO), for example. The metal gate layer can be made by any suitable conductive material such as Tungsten (W), Cobalt (Co), for example.

Still referring to FIG. 4, word lines (not shown) can be formed by depositing a first metal layer (e.g., W) (not shown) on top of the second buffer layer 204. An etch mask with patterns can be formed on the metal layer and an etching process can further be applied to etch the metal layer to form the word lines. Each word line can be connected to the gate structure 210 of each transistor in a row. The etch mask is stripped off and removed to provide the structure shown in FIG. 4.

As shown in FIG. 5, The ILD films 212 can be deposited to fill the spaces that are generated after above-mentioned steps. Any overburdened ILD films can be removed by a surface planarization process such as a chemical mechanical polishing (CMP) process. The ILD films 212 can be any suitable oxide material such as silicon dioxide (SiO₂), Hafnium oxide (HfO), Titanium oxide (TiO), etc.

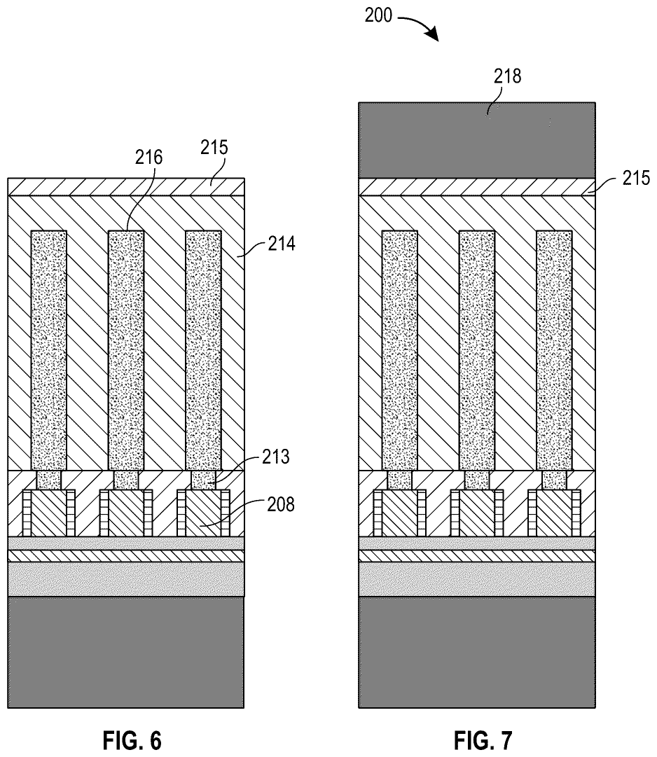

As shown in FIG. 6, multiple doped Si regions 213 are formed and positioned on top of each respective channel structure 208. Multiple capacitors 216 can be formed over the doped Si regions 213. In the illustrated embodiment, each doped Si region 213 is a capacitor contact. Semiconductor material (e.g., SiGe) 214 can be deposited to fill the spaces surrounding the capacitors 216 in the capacitor region. A surface planarization process can remove any overburdened Semiconductor materials, and an oxide layer 215 can be formed on top of the capacitor region.

As shown in FIG. 7, a Si wafer 218 can be bonded to the oxide layer 215 by fusion bonding or any suitable wafer bonding, ensuring the DRAM device 200 is mechanically stable and hermetically sealed in encapsulation.

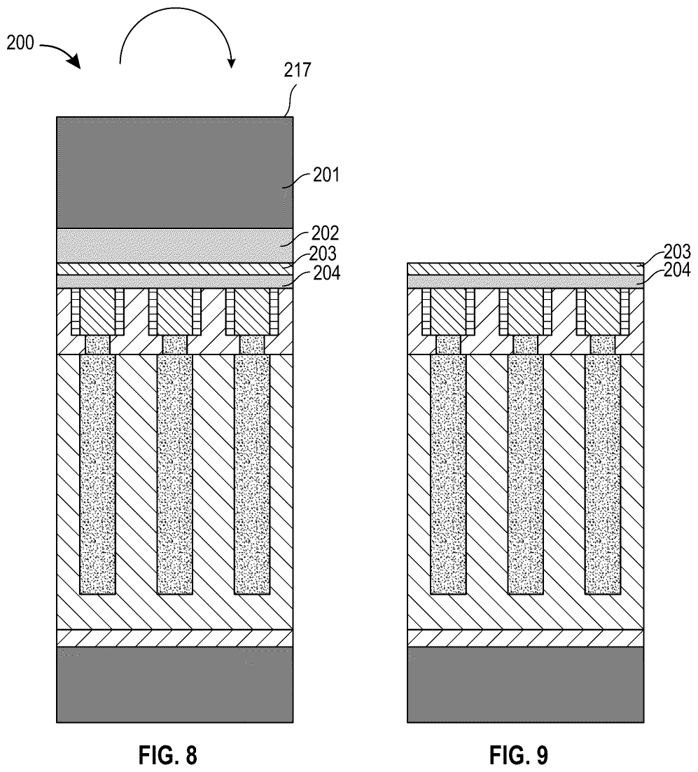

As shown in FIG. 8, the DRAM device 200 can be temporarily flipped. After the flipping process, the substrate 201 is positioned on top of the first buffer layer 202. Accordingly, a backside surface of the substrate is now facing up.

As shown in FIG. 9, the first buffer layer 202 and the substrate 201 can be removed by wafer grinding process, and the first epitaxial layer (e.g., Si) 203 is exposed.

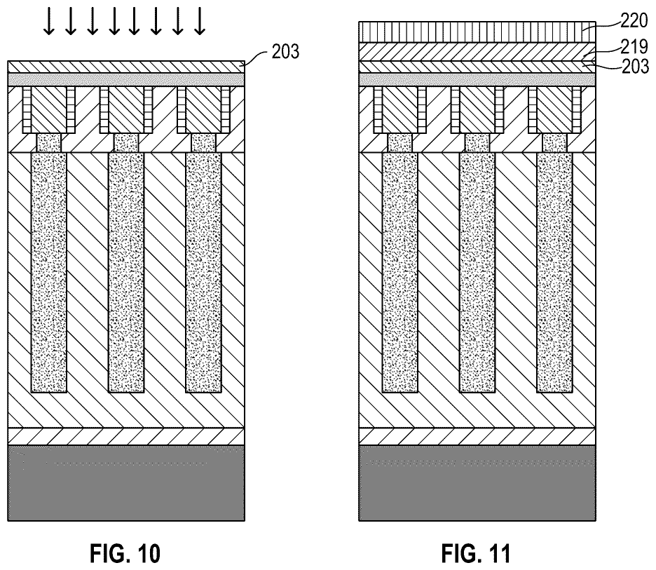

As shown in FIG. 10, a doping process can be applied to dope the exposed first epitaxial layer 203 by introducing impurities to the first epitaxial layer 203. A dopant activation process may be performed when the dopant impurity atoms are diffused or implanted into the first epitaxial layer 203 to form doped regions. The dopant activation process converts the dopant impurity atoms from a relatively inactive state to an electrically active state. Accordingly, the dopant impurity atoms can change the ability of the first epitaxial layer 203 to conduct electricity.

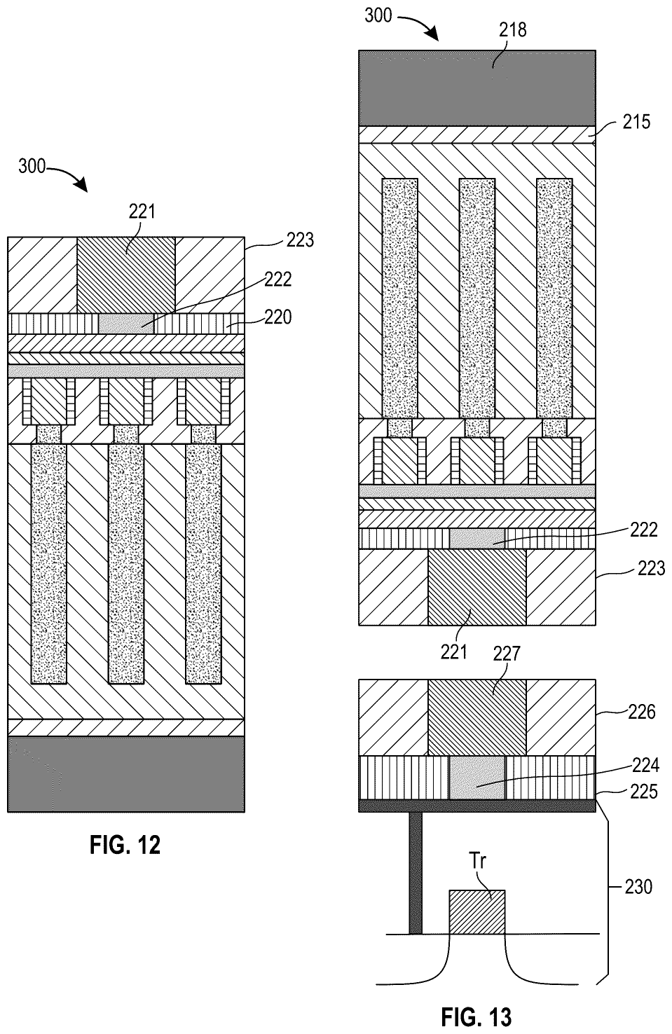

As shown in FIG. 11, a second metal layer (e.g., W) 219 can be formed on the first epitaxial layer 203, and a hard mask (e.g., SiN) 220 can be deposited on the second metal layer 219. An etch mask with patterns can be formed on the hard mask 220 and an etching process can be further performed to etch the hard mask 220 and the second metal layer 219 to form bit lines. The etch mask is stripped off and removed, and oxide materials can be filled into the spaces between the bit lines as shown in FIG. 12.

As also shown in FIG. 12, a first contact 222 can be embedded in the hard mask layer 220, and a first wafer 223 can be positioned on top of the hard mask 220. An etch mask with patterns can be formed on the first wafer 223 and an etching process can be further performed to etch the hard mask to uncover a pad region. Metal materials such as Cu, Aluminum (Al), and W can be filled into the pad to form a first bonding pad 221. The etch mask is stripped off and removed.

FIGS. 13-15 show a cross-sectional view of an exemplary method of integrating the 4F² vertical DRAM cell 100 with a peripheral circuit 130 in accordance with embodiments of the present disclosure.

As shown in FIG. 13, the DRAM device 300 can be flipped back to its original position. After the flipping process, the silicon wafer 218 is positioned on the top of the oxide layer 215. A second wafer 226, having a second embedded bonding pad 227, can be positioned below the first wafer 223, having a first embedded bonding pad 221. The second wafer 226, having a second embedded bonding pad 227, can be formed over an insulating layer (e.g., SiN) 225 having a second contact 224. The hard mask 220 and the insulating layer 225 can insulate the first embedded bonding pad 221 and the second embedded bonding pad 22. Further, the insulating layer 225, having a second contact 224, can be vertically connected to the periphery circuit 230 through the second contact 224.

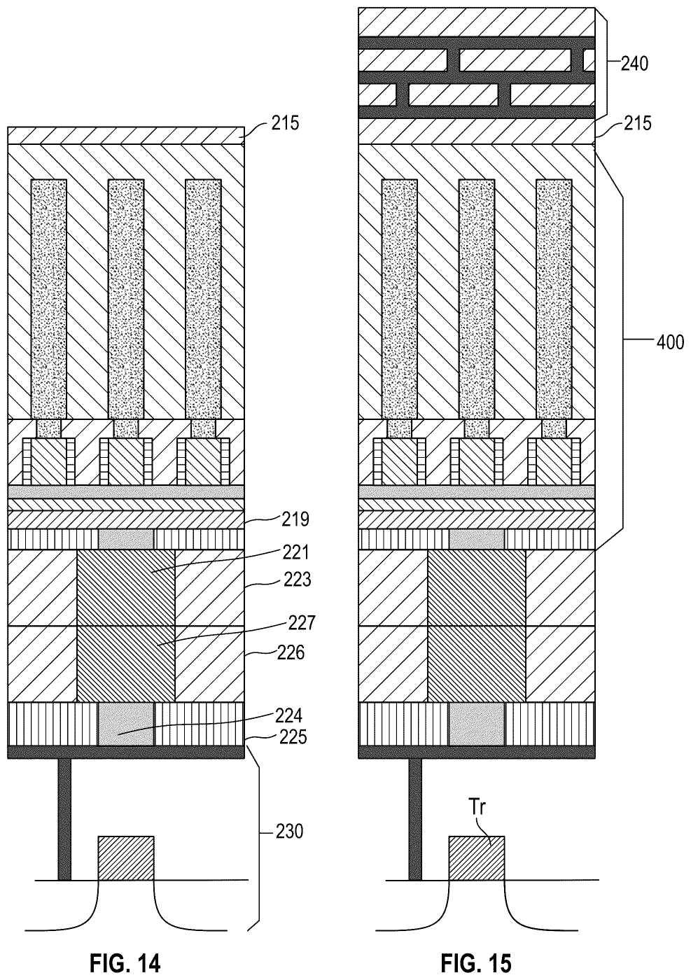

As shown in FIG. 14, the first wafer 223 and the second wafer 226 can be bonded by a suitable hybrid bonding technique. Hybrid bonding may include fusion bonding with the first embedded metal pad 221 and the second embedded metal pad 227, which allows face-to-face connection of the wafers. Accordingly, an interconnection can be formed after the hybrid bonding process. Word lines (not shown) and bit lines 219 can be connected through contacts to bottom bonded wafers. Hybrid bonding vertically connects wafer-to-wafer via closely spaced metal pads, thus increasing the cell density.

As shown in FIG. 15, BEOL metal interconnects 240 can be formed on top of the oxide layer 215. In the semiconductor fabrication process, BEOL 240 can be formed by depositing metal interconnect layers. The DRAM device 400 can be interconnected with wiring by deposited metalization layers in BEOL 240.

The various embodiments described herein offer several advantages. Conventionally, 4F² vertical DRAM has a weakness in that the channel material like a IGZO is formed on a pass gate transistor which causes low current and other undesirable characteristics due to high interface trap. In the present disclosure, a gate transistor with epitaxial layer silicon can be formed in the vertical channel, for example. The epitaxial layer can have higher purity silicon by epitaxy than the silicon in the substrate. Therefore, the current flow can be increased between the source and drain due to the low resistance in the epitaxial layer. Further, in the present disclosure, hybrid bonding through wafer backside can be applied to connect word lines and bit lines with the periphery circuit vertically. Accordingly, the cell size is decreased, and the cell density can be increased.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claims is:

1. A method of integrating a semiconductor device with a periphery circuit including forming the semiconductor device that comprises:
forming a stack of alternatively deposited semiconductor layers on a surface of a substrate, the stack of alternative deposited layers including a first buffer layer formed on the substrate, a first epitaxial layer formed on the first buffer layer, a second buffer layer formed on the first epitaxial layer, and a second epitaxial layer formed on the second buffer layer;
etching the second epitaxial layer to form a plurality of vertical channel structures;
depositing a gate dielectric layer and a gate metal layer on at least one of the plurality of channel structures to form a plurality of GAA (vertical gate all around) transistors;
forming a plurality of vertical capacitors in a capacitor region above the plurality of vertical GAA transistors;
forming an oxide layer on top of the capacitor region; and
depositing a hard mask on a first metal layer formed on the second epitaxial layer.

2. The method of claim 1, wherein:
the first buffer layer and the second buffer layer include Silicon Germanium (Sige); and
the first epitaxial layer and the second epitaxial layer include Silicon (Si).

3. The method of claim 1, further comprising:
depositing a second metal layer on top of the second buffer layer; and
etching the second metal layer to form a plurality of word lines that connect to the plurality of vertical GAA transistors.

4. The method of claim 1, wherein the plurality of channel structures are formed in a transistor region that is filled with interlayer dielectric (ILD) films.

5. The method of claim 1, further comprising:
forming a plurality of contact regions, wherein at least one of the contact regions forms on top of at least one of the plurality of vertical GAA transistors through a contact region.

6. The method of claim 5, wherein the plurality of contact regions include doped Si.

7. The method of claim 1, wherein forming the plurality of vertical capacitors further comprises:
depositing semiconductor material to fill spaces surrounding each of the plurality of vertical capacitors in a capacitor region; and
forming an oxide layer on top of the capacitor region.

8. The method of claim 7, wherein the semiconductor material can include SiGe.

9. The method of claim 1, wherein forming a plurality of bit lines comprises:
forming a wafer on the oxide layer by fusion bonding;
flipping the semiconductor device so that the substrate is in a top position and a backside of the substrate is facing up in a vertical direction;
removing the substrate and the first buffer layer to expose the first epitaxial layer;
doping the first epitaxial layer;
depositing the metal layer on the first epitaxial layer;
forming a hard mask on the metal layer;
forming an etch mask with patterns on the hard mask to uncover the plurality of bit lines; and
etching the hard mask and the metal layer to form the plurality of bit lines.

10. The method of claim 9, further comprises forming a first contact in the hard mask.

11. The method of claim 1, wherein the semiconductor device is a 4F² vertical dynamic random-access memory (DRAM) device.

12. A method of integrating a semiconductor device with a periphery circuit including connecting the semiconductor device to a periphery circuit that comprises:
forming a vertical DRAM cell including a plurality of vertical transistors, a plurality of capacitors and an oxide layer;
forming a silicon (Si) wafer on top of the oxide layer by fusion bonding;
flipping the vertical DRAM cell so that a substrate is in a top position and a backside of the substrate is facing up in a vertical direction;
grinding and removing the substrate to expose a first epitaxial layer;
doping the first epitaxial layer;
forming a first wafer embedded with a first bonding pad on a hard mask that is deposited on a plurality of bit lines;
flipping the vertical DRAM cell back to its original position;
forming a second wafer embedded with a second bonding pad that is formed on an insulating layer;
connecting the insulating layer to the periphery circuit through a second contact that is embedded in the insulating layer;
bonding the first wafer and the second wafer by hybrid bonding; and
forming back end of lines (BEOL) on top of the DRAM cell to encapsulate the semiconductor device.

13. The method of claim 12, wherein forming BEOL on top of the DRAM cell comprises grinding and removing the silicon wafer to expose the oxide layer.

14. The method of claim 12, wherein forming the plurality of bit lines comprises:
depositing a metal layer on the first epitaxial layer;
depositing the hard mask on the metal layer;
depositing an etch mask with patterns on the hard mask; and
etching the hard mask and metal layer to form a plurality of bit lines.

15. The method of claim 12, wherein the plurality of vertical transistors vertically connect to a plurality of word lines and a plurality of bit lines.

16. The method of claim 15, wherein the periphery circuit is under the vertical DRAM cell and vertically connects to the plurality of word lines and the plurality of bit lines through the first bonding pad and the second bonding pad.

17. The method of claim 12, wherein at least one of the plurality of transistors includes a vertical channel that is formed by epitaxial growth.

18. The method of claim 16, wherein the vertical channel is formed by etching a second epitaxial layer that is originally formed above the first epitaxial layer.

19. The method of claim 18. wherein the second epitaxial layer includes silicon (Si).

20. The method of claim 12, wherein the bonding pad includes at least one of copper (Cu), aluminum (Al), or tungsten (W).
